(19) United States
(12) Patent Application Publication
(10) Pub. No.: US 2014/0051256 A1
(43) Pub. Date: Feb. 20, 2014

(54) ETCH WITH MIXED MODE PULSING

(71) Applicants: Qinghua ZHONG, Fremont, CA (US); Siyi LI, Fremont, CA (US); Armen KIRAKOSIAN, Walnut Creek, CA (US); Yifeng ZHOU, Fremont, CA (US); Ramkumar VINNAKOTA, Sunnyvale, CA (US); Ming-Shu KUO, San Ramon, CA (US); Srikanth RAGHAVAN, Fremont, CA (US); Yoshie KIMURA, Castro Valley, CA (US); Tae Won KIM, Dublin, CA (US); Gowri KAMARTHY, Pleasanton, CA (US)

(72) Inventors: Qinghua ZHONG, Fremont, CA (US); Siyi LI, Fremont, CA (US); Armen KIRAKOSIAN, Walnut Creek, CA (US); Yifeng ZHOU, Fremont, CA (US); Ramkumar VINNAKOTA, Sunnyvale, CA (US); Ming-Shu KUO, San Ramon, CA (US); Srikanth RAGHAVAN, Fremont, CA (US); Yoshie KIMURA, Castro Valley, CA (US); Tae Won KIM, Dublin, CA (US); Gowri KAMARTHY, Pleasanton, CA (US)

(73) Assignee: LAM RESEARCH CORPORATION, Fremont, CA (US)

(21) Appl. No.: 13/586,793

(22) Filed: Aug. 15, 2012

(51) Int. Cl. H01L 21/3065

(52) U.S. Cl. 438/717; 438/723; 257/E21.218

(57) ABSTRACT

A method for etching a dielectric layer disposed below a patterned organic mask with features, with hardmasks at bottoms of some of the organic mask features is provided. An etch gas is provided. The etch gas is formed into a plasma. A bias RF with a frequency between 2 and 60 MHz is provided that provides pulsed bias with a pulse frequency between 10 Hz and 1 kHz wherein the pulsed bias selectively deposits on top of the organic mask with respect to the dielectric layer.

### BACKGROUND OF THE INVENTION

### Field of the Invention

The invention relates to a method of forming semiconductor devices on a semiconductor wafer. More specifically, the invention relates to selectively etching a dielectric layer with respect to an organic mask and a hardmask.

In forming semiconductor devices, some devices may be formed by selectively etching an etch layer with respect to an organic mask and hardmask.

### SUMMARY OF THE INVENTION

To achieve the foregoing and in accordance with the purpose of the present invention, a method for etching a dielectric layer disposed below a patterned organic mask with features, with hardmasks at bottoms of some of the organic mask features is provided. An etch gas is provided. The etch gas is formed into a plasma. A bias RF with a frequency between 2 and 60 MHz is provided that provides pulsed bias with a pulse frequency between 10 Hz and 1 kHz wherein the pulsed bias selectively deposits on top of the organic mask with respect to the dielectric layer.

In another manifestation of the invention, a method for etching a dielectric layer disposed below a patterned organic mask with features, with hardmask at bottoms of some of the organic mask features, comprising a plurality of cycles is provided. Each cycle comprises selectively depositing on top of the patterned organic mask with respect to the dielectric layer and selectively etching the dielectric layer with respect to the patterned organic mask and hardmask.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a flow chart of an embodiment of the invention.

FIGS. 2A-C are schematic cross-sectional views of a stack etch according to an embodiment of the invention.

FIG. 3 is a schematic view of a plasma processing chamber that may be used in an embodiment of the invention.

FIG. 4 is a schematic view of a computer system that may be used in practicing the invention.

FIG. 5 is a more detailed flow chart of the selective mask deposition phase.

FIG. 6 is a more detailed flow chart of selective etch layer etch phase.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In the formation of semiconductor devices, such as in the formation of FinFET spacer, it is desirable to etch a dielectric layer, such as silicon oxide, with respect to an organic mask, such as photoresist, and a hardmask, such as silicon nitride (SiN). In other semiconductor processes, it is desirable to etch an etch layer disposed below a patterned organic mask with features, where a hardmask is formed on the bottoms of some of the organic mask features.

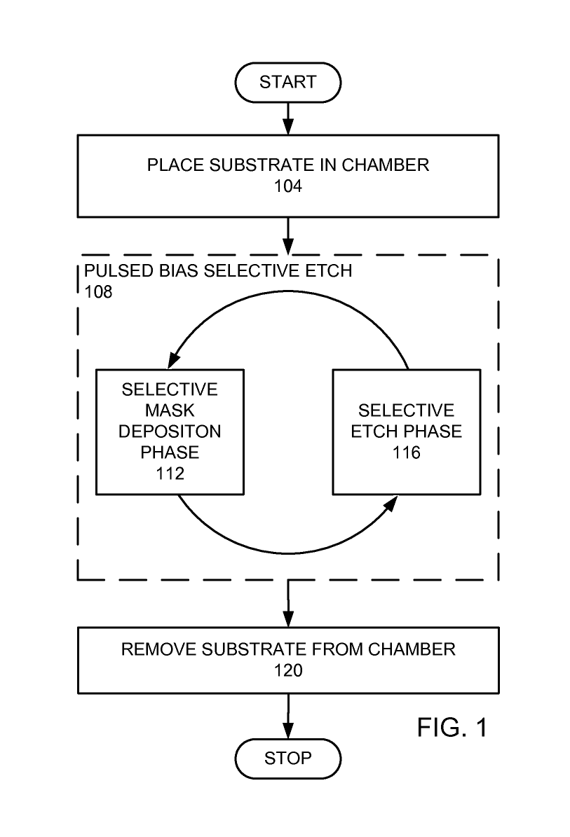

FIG. 1 is a high level flow chart of an embodiment of the invention. In this embodiment, a substrate with an etch layer disposed under a patterned organic mask with features and a hardmask at the bottom of features of the patterned organic is placed in an etch chamber (step 104). A pulsed bias selective etch is provided by the etch chamber (step 108), where the pulsed bias selective etch (step 108) comprises a plurality of cycles where each cycle comprises a selective mask deposition phase (step 112) and a selective etch layer etch phase (step 116). The substrate is removed from the etch chamber (step 120).

### Example

### Etch Layer with Organic Mask and Hardmask

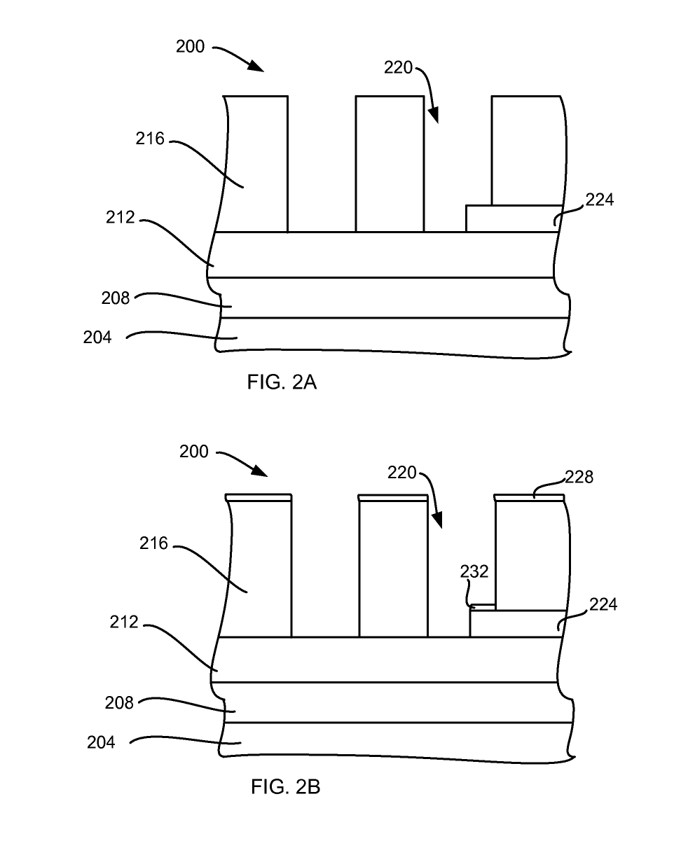

In a preferred embodiment of the invention, a substrate with an etch layer disposed under a patterned organic mask with features and a hardmask at the bottom of features of the patterned organic is placed in an etch chamber (step 104). FIG. 2A is a schematic cross-sectional view of a stack 200 with a substrate 204 with an etch stop layer 208 disposed below an etch layer 212, disposed below an organic mask 216 with organic mask features 220. At the bottom of some of the organic mask features is a hardmask 224. In this example, one or more layers may be disposed between the substrate 204 and the etch stop layer 208, or between the etch stop layer 208 and the etch layer 212, or the etch layer 212 and the organic mask 216 or hardmask 224. In this example, the organic mask 216 is a photoresist, the hardmask 224 is Titanium nitride (TiN), and the etch layer 212 is silicon oxide (SiO).

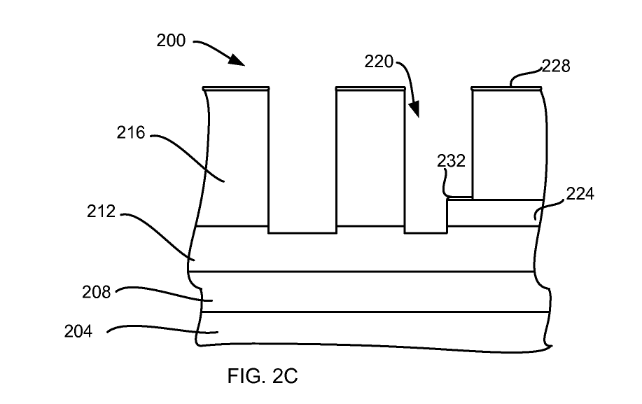

FIG. 3 schematically illustrates an example of a plasma processing system 300 which may be used in one embodiment of the present invention. The plasma processing system 300 includes a plasma reactor 302 having a plasma processing chamber 304 therein defined by a chamber wall 350. A plasma power supply 306, tuned by a match network 308, supplies power to a TCP coil 310 located near a power window 312 that provides the power to the plasma processing chamber 304 to create a plasma 314 in the plasma processing chamber 304. The TCP coil (upper power source) 310 may be configured to produce a uniform diffusion profile within processing chamber 304. For example, the TCP coil 310 may be configured to generate a toroidal power distribution in the plasma 314. The power window 312 is provided to separate the TCP coil 310 from the plasma processing chamber 304 while allowing energy to pass from the TCP coil 310 to the plasma processing chamber 304. A wafer bias voltage power supply 316 tuned by a match network 318 provides power to an electrode 320 to set the bias voltage on the silicon substrate 204, which is supported by the electrode 320, so that the electrode 320 in this embodiment is also a substrate support. A pulse controller 352 causes the bias voltage to be pulsed. The pulse controller 352 may be between the match network 318 and the substrate support, or between the bias voltage power supply 316 and the match network 318, or between the controller 324 and the bias voltage power supply 316 or in some other configuration to cause the bias voltage to be pulsed. A controller 324 sets points for the plasma power supply 306 and the wafer bias voltage supply 316.

The plasma power supply 306 and the wafer bias voltage power supply 316 may be configured to operate at specific radio frequencies such as, for example, 13.56 MHz, 27 MHz, 2 MHz, 400 kHz, or combinations thereof. Plasma power supply 306 and wafer bias power supply 316 may be appropriately sized to supply a range of powers in order to achieve desired process performance. For example, in one embodiment of the present invention, the plasma power supply 306 may supply the power in a range of 300 to 10000 Watts, and the wafer bias voltage power supply 316 may supply a bias voltage in a range of 10 to 2000 V. In addition, the TCP coil 310 and/or the electrode 320 may be comprised of two or more sub-coils or sub-electrodes, which may be powered by a single power supply or powered by multiple power supplies.

As shown in FIG. 3, the plasma processing system 300 further includes a gas source/gas supply mechanism 330. The gas source includes a first component gas source 332, a second component gas source 334, and optionally, additional component gas sources 336. The various component gases will be discussed below. The gas sources 332, 334, and 336 are in fluid connection with process chamber 304 through a gas inlet 340. The gas inlet may be located in any advantageous location in process chamber 304, and may take any form for injecting gas. Preferably, however, the gas inlet may be configured to produce a “tunable” gas injection profile, which allows independent adjustment of the respective flow of the gases to multiple zones in the process chamber 304. The process gases and byproducts are removed from the chamber 304 via a pressure control valve 342, which is a pressure regulator, and a pump 344, which also serves to maintain a particular pressure within the plasma process chamber 304 and also provides a gas outlet. The gas source/gas supply mechanism 330 is controlled by the controller 324. A Kiyo system by Lam Research Corporation may be used to practice an embodiment of the invention.

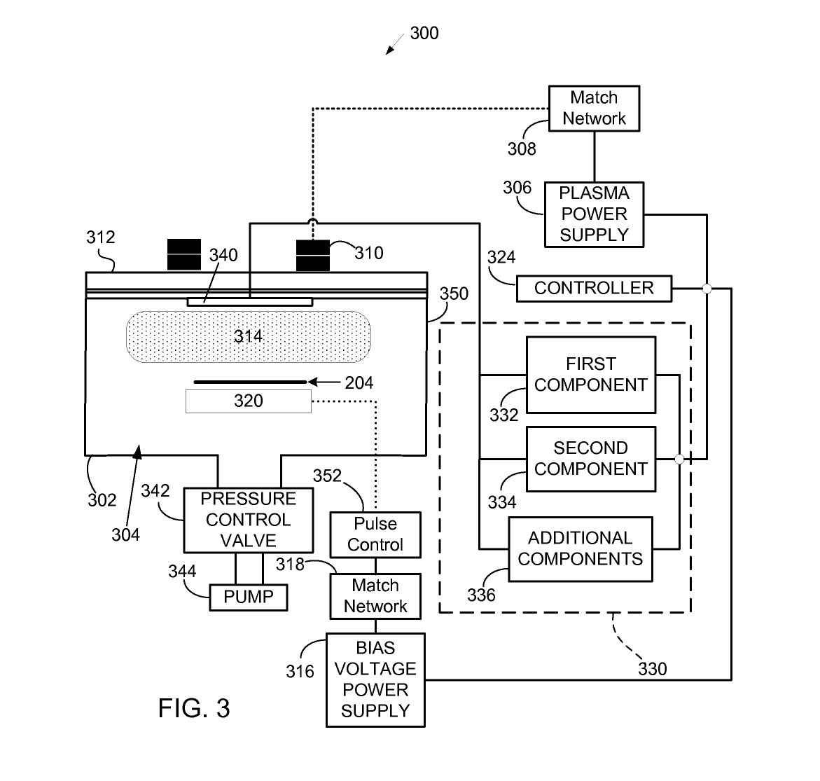

FIG. 4 is a high level block diagram showing a computer system 400, which is suitable for implementing a controller 324 used in embodiments of the present invention. The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

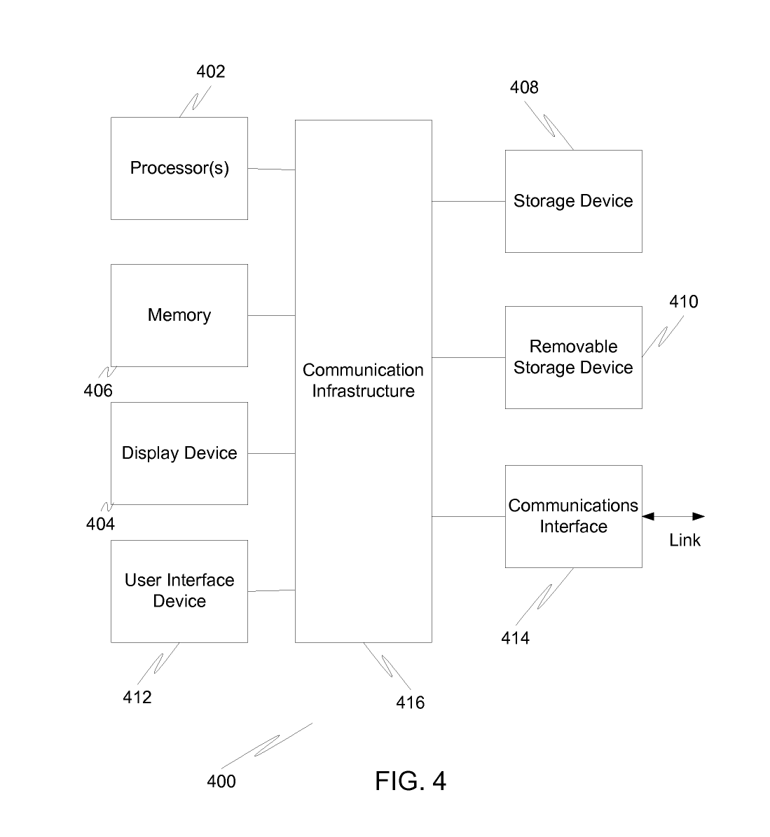

A pulsed bias selective etch is provided by the etch chamber (step 108), where the pulsed bias selective etch (step 108) comprises a plurality of cycles where each cycle comprises a selective mask deposition phase (step 112) and a selective etch layer etch phase (step 116). FIG. 5 is a more detailed flow chart of the selective mask deposition phase (step 112). A deposition gas is flowed from the gas source 330 to the processing chamber 304 (step 504). The deposition gas is formed into a plasma (step 508). A deposition bias is provided (step 512). The flow of the deposition gas is stopped (step 516).

An example of a recipe for providing a selective mask deposition phase provides a chamber pressure of 3 mTorr. A deposition gas of 100 sccm Ar, 50 sccm H₂, and 15 sccm C₄F₈ is flowed into the process chamber 304 (step 504). 400 watts of RF at 13.56 MHz is provided by the TCP coil 310 to form the deposition gas into a plasma (step 508). No deposition bias is provided by the wafer bias power supply 316 (step 512), since the duty cycle is off during the selective mask deposition phase to provide a net deposition. In this example, since the deposition gas is the same recipe as the etch gas, the flow of the deposition gas does not need to be stopped.

FIG. 2B is a schematic cross-sectional view of the stack 200 after the selective mask deposition phase (step 112) is completed. A deposition 228 has been selectively deposited on top of the organic mask 216 with respect to the etch layer 212. A deposition 232 has also been selectively deposited on top of the hardmask 224 with respect to the etch layer 212.

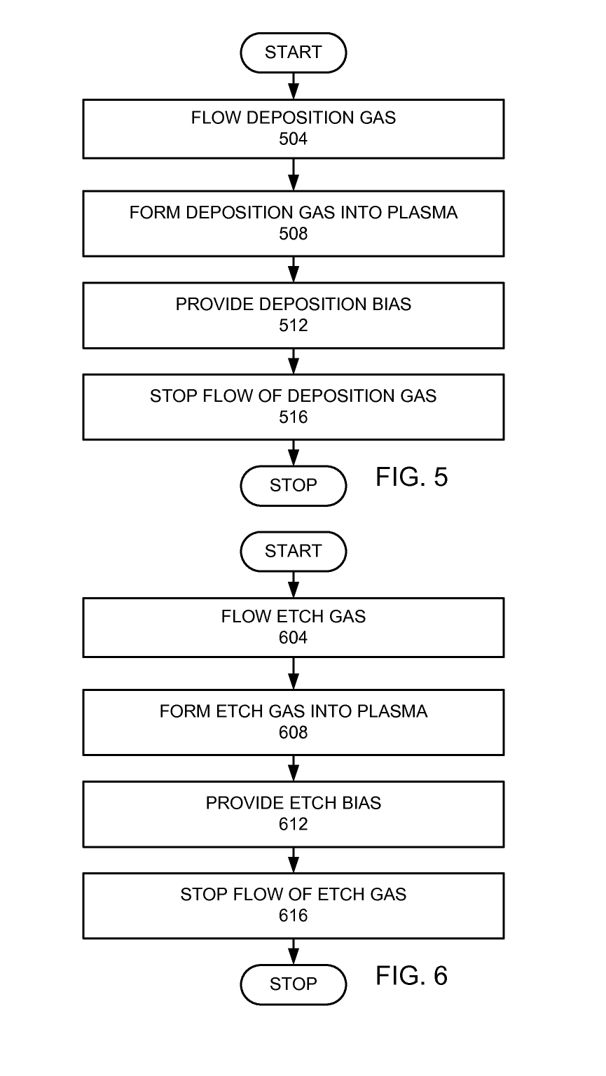

FIG. 6 is a more detailed flow chart of the selective etch phase (step 116). An etch gas is flowed from the gas source 330 to the processing chamber 304 (step 604). The etch gas is formed into a plasma (step 608). An etch bias is provided (step 612). The flow of the etch gas is stopped (step 616).

An example of a recipe for providing an etch provides a chamber pressure of 3 mTorr. An etch gas of 100 sccm Ar, 50 sccm H₂, and 15 sccm C₄F₈ is flowed into the process chamber 304 (step 604). 400 watts of RF at 13.56 MHz is provided by the TCP coil 310 to form the etch gas into a plasma (step 608). An etch bias of 500 volts, generated by providing an RF at 13.56 MHz, is provided by turning on the bias power from the wafer bias power supply 316 during a pulsed bias, where the etching phase is during the on part of the duty cycle (step 612). In this example, since the etch gas is the same recipe as the deposition gas, the flow of the etch gas does not need to be stopped. There may be some deposition during this phase, but during this phase there is no net deposition. More preferably, there is a net removal of the deposition.

FIG. 2C is a schematic cross-sectional view of the stack 200 after the etch phase is completed. The etch layer 212 has been selectively etched, while some of the deposition 228, 232 has also been removed while protecting the organic mask 216 and hardmask 224.

If the etch phase does not remove all of the deposition, so that the deposition prevents any of the photoresist and hardmask from being etched, then the resulting etch may have an infinite selectivity for etching the etch layer with respect to both the photoresist mask and hardmask. Preferably, the frequency of the cycle is between 10 Hz to 1 kHz, requiring a pulsed bias between 10 Hz and 1 kHz. Although in this example, the RF bias is 13.56 MHz, in various embodiments, the bias by be provided with an RF between 2 to 60 MHz to the electrode supporting the substrate. In this embodiment, there is a 75% duty cycle, where the bias is on 75% of the time. In other embodiments, the duty cycle is between 10% and 90%.

### Formation of FinFET Spacer

In another manifestation of the invention, a FinFET spacer is formed using an embodiment of the invention. To form a FinFET spacer, it is desirable to etch a SiN layer without etching a silicon fin or silicon oxide. It has found that the pulsed bias allows the selective etching of the SiN layer with reduced etching of both the silicon fin and SiO.

### Other Embodiments

Another embodiment of the invention provides bias pulse duty cycle modulation, where the duty cycle changes over time. In another embodiment, the deposition is only provided on top of the organic mask, with minimal etching of the organic mask, due to the protection of the deposition layer and minimal etching of the hardmask due to the depth of the hardmask or the material of the hardmask during etching of the etch layer. Deposition selectivity may be based on the deposition selectivity of different materials or deposition selectivity based on aspect ratio. Deposition selectivity based on aspect ratio may deposit more on tops of the higher organic mask tops. In an above embodiment, the deposition gas is the same as the etch gas. In another embodiment, the deposition gas may be different than the etch gas. In such an embodiment, the difference between the etch gas and deposition gas may be provided by pulsing a single gas. In another embodiment, different gases may be switched. In an embodiment, the etch gas and/or deposition gas may comprise a fluorocarbon, which includes hydrofluorocarbons, such as C₄F₆, C₄F₈, C₅F₈, CHF₃, CH₂F₂, and CH₃F. The fluorocarbon may be used with N₂, H₂, O₂, or other inert gases. Generally, gas pulsing cannot be switched as quickly as bias pulsing. The faster bias pulsing provides a better etch, due to the fast switching. On the other hand, gas pulsing provides an additional control.

An example of a both gas and bias pulsing process provides a deposition with a chamber pressure of 3 mTorr. A deposition gas of 100 sccm Ar and 50 sccm H₂ is flowed into the process chamber 304 (step 504). 400 watts of RF at 13.56 MHz is provided by the TCP coil 310 to form the deposition gas into a plasma (step 508). A bias of 500 volts is generated by providing an RF at 13.56 MHz by turning on the bias power from the wafer bias power supply 316 applied to the electrode 320 with a bias pulse frequency of 20 to 200 Hz and a duty cycle between 10% and 90% (step 512). The flow of the deposition gas is then stopped (step 516). This step is provided for 2 to 30 seconds.

An example of a recipe for providing an etch during a mixed mode process provides a chamber pressure of 3 mTorr. An etch gas of 100 sccm Ar, 50 sccm H₂, and 15 sccm C₄F₈ is flowed into the process chamber 304 (step 604). 400 watts of RF at 13.56 MHz is provided by the TCP coil 310 to form the etch gas into a plasma (step 608). A bias of 500 volts is generated by providing an RF at 13.56 MHz by turning on the bias power from the wafer bias power supply 316 applied to the electrode 320 with no pulsing (step 612). The flow of the etch gas is then stopped (step 616). There may be some deposition during this phase, but during this phase there is no net deposition. More preferably, there is a net removal of the deposition. This step is provided for 2 to 30 seconds. The two steps are cyclically repeated for a plurality of times.

In various embodiments, the hardmask may be TiN, some other metal or non-metal hardmask, for example, Ta; Ti; Ta₂O₃; Ti₂O₃; Al₂O₃, or SiN. Preferably, the etch layer is a dielectric layer. Preferably, the hardmask is made of a nitride or metal containing material.

Preferably the process is performed over at least 50 cycles. More preferably, the process is performed over at least 100 cycles.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

1. A method for etching a dielectric layer disposed below a patterned organic mask with features, with hardmasks at the bottom of some of the organic mask features, comprising:
providing an etch gas;
forming the etch gas into a plasma; and
providing a bias RF with a frequency between 2 and 60 MHz that provides pulsed bias with a pulse frequency between 10 Hz and 1 kHz wherein the pulsed bias selectively deposits on top of the organic mask with respect to the dielectric layer.

2. The method, as recited in claim 1, further comprising modulating a duty cycle frequency of the pulsed bias.

3. The method, as recited in claim 2, further comprising modulating the etch gas for a plurality of cycles, wherein each cycle comprises:
providing a first gas;
stopping the first gas;
providing a second gas; and
stopping the second gas.

4. The method, as recited in claim 3, wherein the pulsed bias further selectively deposits on top of the hard mask with respect to the dielectric layer.

5. The method, as recited in claim 4, wherein the bias is pulsed for at least 100 cycles.

6. The method, as recited in claim 5, wherein the first gas comprises a fluorocarbon.

7. The method, as recited in claim 6, wherein the dielectric layer is a silicon oxide based layer.

8. The method, as recited in claim 7, wherein the hardmask is a metal or nitride containing layer.

9. The method, as recited in claim 2, wherein the pulsed bias further selectively deposits on top of the hard mask with respect to the dielectric layer.

10. The method, as recited in claim 1, further comprising modulating the etch gas for a plurality of cycles, wherein each cycle comprises:
providing a first gas;
stopping the first gas;
providing a second gas different from the first gas; and
stopping the second gas.

11. A method for etching a dielectric layer disposed below a patterned organic mask with features, with hardmask at the bottom of some of the organic mask features, comprising a plurality of cycles, wherein each cycle comprises:
selectively depositing on top of the patterned organic mask with respect to the dielectric layer; and
selectively etching the dielectric layer with respect to the patterned organic mask and hardmask.

12. The method, as recited in claim 11, wherein the selective depositing provides a different bias voltage than the selective etching.

13. The method, as recited in claim 12, wherein the bias voltage is provided by a bias RF with a frequency between 2 and 60 MHz, wherein the bias is pulsed at a pulse frequency between 10 Hz and 1kHz to provide the cycling between the selective deposition and selective etching.

14. The method, as recited in claim 13, wherein during the selective depositing the bias voltage is off and during the selective etching the bias voltage is on providing a duty cycle.

15. The method, as recited in claim 14, further comprising modulating a duty cycle frequency of the pulsed bias.

16. The method, as recited in claim 15, further comprising:
providing a deposition gas during the selective deposition; and
providing an etch gas during the selective etching, wherein the deposition gas is different than the etch gas.
